(19) United States
(12) Patent Application Publication
(10) Pub. No.: US 2025/0324530 A1
(43) Pub. Date: Oct. 16, 2025

(54) DRIVE CARRIER FOR DATA STORAGE SYSTEMS

(71) Applicant: Sanmina Corporation, San Jose, CA (US)

(72) Inventors: Odie Banks Killen, JR., Colorado Springs, CO (US); Kent Murphy, Colorado Springs, CO (US); Barry Boes, Colorado Springs, CO (US); Qilu He, Colorado Springs, CO (US)

(21) Appl. No.: 19/175,849

(22) Filed: Apr. 10, 2025

Related U.S. Application Data
(60) Provisional application No. 63/633,583, filed on Apr. 12, 2024.

(51) Int. Cl. H05K 7/14; G11B 33/04; G11B 33/14; H05K 9/00

(52) U.S. Cl. CPC H05K 7/1401; G11B 33/04; G11B 33/1493; H05K 9/0007

(57) ABSTRACT

Storage media carriers may include a frame and an end cap coupled with the frame. The end cap may include a top surface, a first side surface extending away from the top surface, and a second side surface extending away from the top surface. According to another example, a data storage assembly may include a plurality of storage media devices, and a respective carrier comprising a frame coupled to each of storage media device, where each frame includes an end cap that extends over and covers a longitudinal end surface of a respective storage media device and wraps around a portion of a side surface of the respective storage media device. Other aspects, embodiments, and features are also included.

### PRIORITY CLAIM

This application claims priority to and the benefit of provisional patent application No. 63/633,583 filed in the U.S. Patent and Trademark Office on Apr. 12, 2024, the entire content of which is incorporated herein by reference as if fully set forth below in its entirety and for all applicable purposes.

### TECHNICAL FIELD

The technology discussed below relates generally to data storage systems, and more specifically to drive carriers for data storage systems.

### BACKGROUND

Computer and network systems such as data storage systems (e.g., server systems, cloud storage systems, just a bunch of drives/disks (JBOD), just a bunch of flash (JBOF), personal computers, and workstations) typically include data storage devices for storing and retrieving data. These data storage devices can include hard disk drives (HDDs), solid state drives (SSDs), etc., that include both rotating and solid state data storage elements.

As computer systems and networks grow in numbers and capability, there is a need for ever increasing storage capacity. Data centers, cloud computing facilities, and other at-scale data processing systems have further increased the need for digital data storage systems capable of transferring and holding immense amounts of data. Data centers can house large quantities of data storage systems stored in various rack-mounted and high-density storage configurations.

While densities and workloads for the data storage systems increase, individual data storage devices can experience increased failure rates due to the increased densities and higher operating temperatures. Features and systems that can improve the operation and function of data storage systems are generally desirable.

### DRAWINGS

FIG. 1 is an isometric view of a data storage system according to at least one embodiment configured as a general purpose I/O module.

FIG. 2 is a front isometric view of a carrier according to at least one embodiment.

FIG. 3 is a front isometric view of the carrier in FIG. 2 with a storage media device coupled with the carrier according to at least one embodiment.

FIG. 4 is a back isometric view of the carrier in FIG. 2 according to at least one embodiment.

FIG. 5 is a back isometric view of the carrier in FIG. 2 with a storage media device coupled with the carrier according to at least one embodiment.

FIG. 6 is a top plan view of the carrier of FIG. 2 according to at least one embodiment.

FIG. 7 is a schematic top plan view of a carrier illustrating one or more aspects of a latching mechanism according to at least one embodiment.

FIG. 8 is a zoomed-in isometric view of a chassis according to at least one embodiment.

FIG. 9 is a flow diagram illustrating at least one implementation of a method for making a data storage system.

### DETAILED DESCRIPTION

The description set forth below in connection with the appended drawings is intended as a description of various configurations and is not intended to represent the only configurations in which the concepts and features described herein may be practiced. The following description includes specific details for the purpose of providing a thorough understanding of various concepts. However, it will be apparent to those skilled in the art that these concepts may be practiced without these specific details. In some instances, well known circuits, structures, techniques and components are shown in block diagram form to avoid obscuring the described concepts and features.

The illustrations presented herein are, in some instances, not actual views of any particular data storage system, data storage assembly, storage media device, carrier, or other specific components of a data storage system, but are merely representations which are employed to describe the present disclosure. Additionally, elements common between figures may retain the same numerical designation.

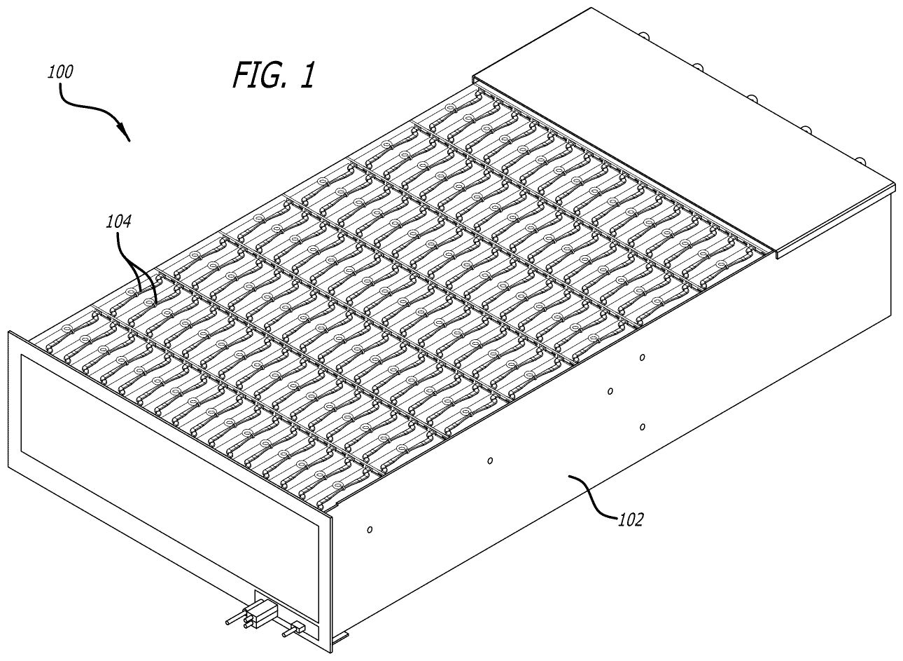

Aspects of the present disclosure relate to data storage systems, including general purpose I/O (input/output) modules, server modules, JBOD (Just a Bunch Of Drives) and JBOF (Just a Bunch Of Flash), by way of example. Example data storage systems may be configured for storage in various rack-mounted and high-density storage configurations. Example data storage systems may include many storage media devices with conventional I/O modules to facilitate a JBOD/JBOF configuration. Referring to FIG. 1, an isometric view of a data storage system 100 is depicted according to at least one embodiment of a data storage system 100. The data storage system 100 may include a chassis 102, which provides a housing or enclosure for various components. Within portions of the chassis 102, the data storage system 100 may include various components. For example, the data storage system 100 may include a controller, including a central processing unit (CPU), one or more fans, and/or other components. The data storage system 100 in the depicted example includes one or more storage media devices 104. The storage media devices 104 may be any known storage media device, including a hard disk drive (HDD), a solid state drive (SSD), etc.

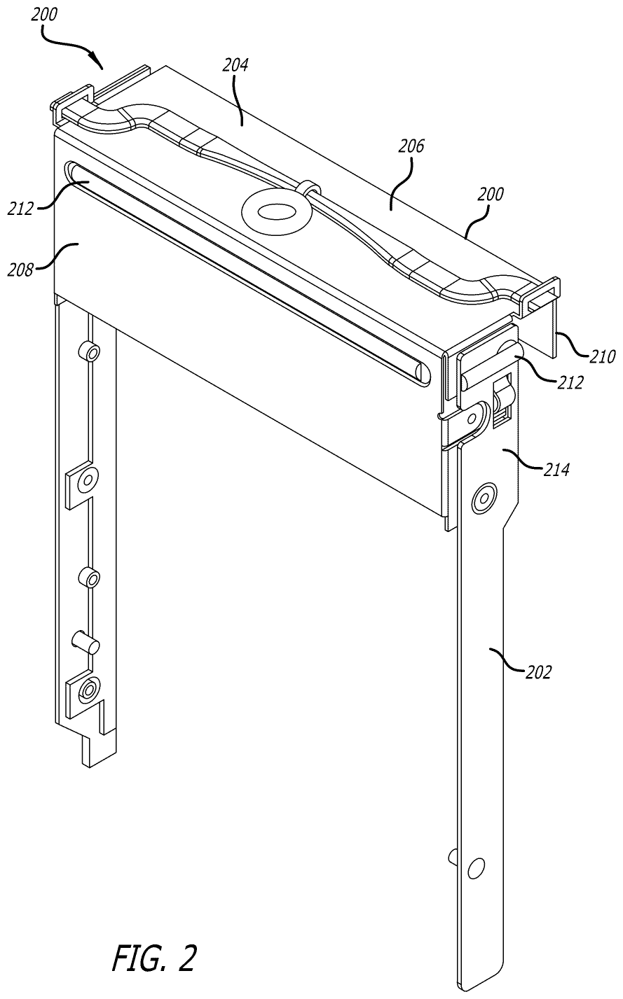

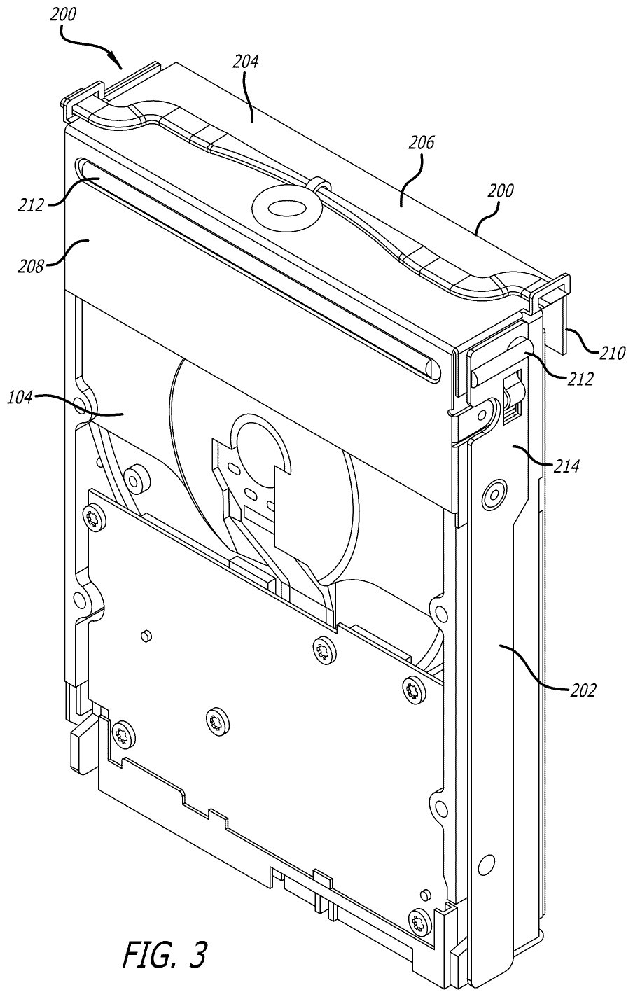

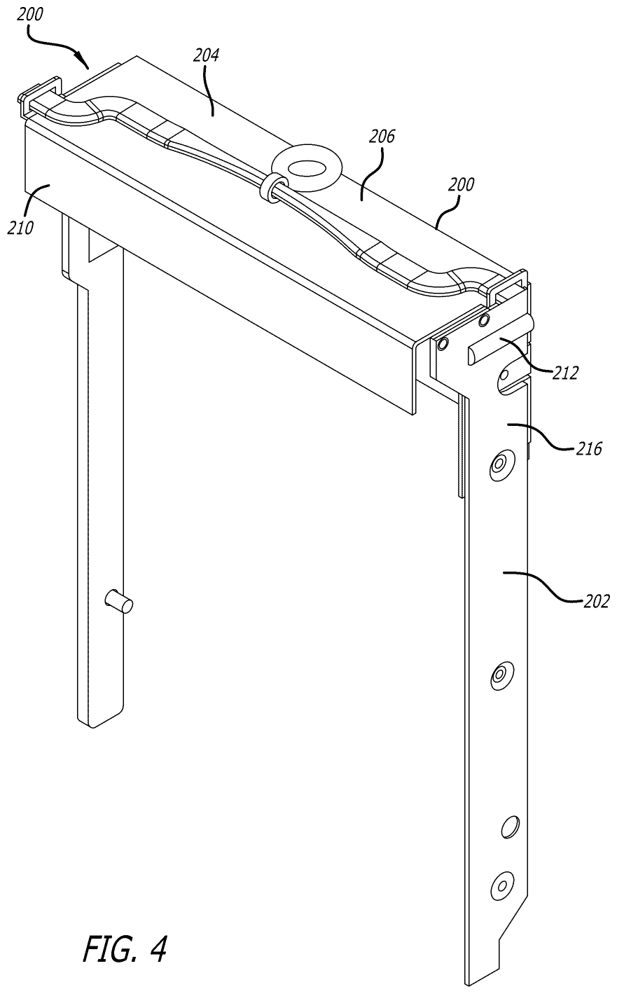

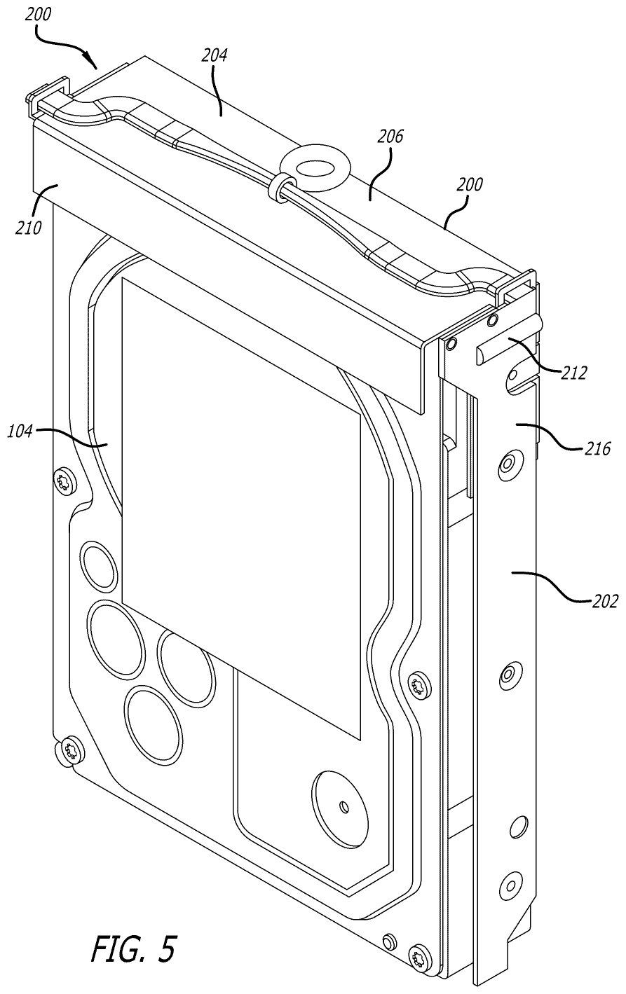

According to various aspects, each storage media device 104 can be coupled to a respective carrier. For example, FIG. 2 is an isometric view of a first side of a carrier 200 according to at least one example, and FIG. 3 is an isometric view of the first side of the carrier 200 with a storage media device 104 coupled to the carrier 200, according to at least one example. Furthermore, FIG. 4 is an isometric view of a second side, opposite the first side, of the carrier 200, and FIG. 5. Is an isometric view of the second side of the carrier 200 with a storage media device 104 coupled to the carrier 200, according to one or more examples.

As depicted in FIGS. 2-5, the carrier 200 may include a frame 202 that couples the carrier 200 to the storage media device 104. The carrier 200 may be formed from a polymer material, a metal, or some combination thereof. In some examples, the carrier 200 may include an end cap 204 that extends over and covers a longitudinal end surface of the storage media device 104. The end cap 204 is further configured to wrap around a portion of a side surface of the storage media device 104. Accordingly, the end cap 204 may include a top surface 206 that extends over and covers the longitudinal end surface of the storage media device 104. The end cap 204 may further include a first side surface 208 that is coupled with the top surface 206, and extends away from the top surface 206 at least substantially transverse to the top surface 206. Additionally, the end cap 204 may include a second side surface 210 (shown more clearly in FIGS. 4 & 5) that is coupled with the top surface 206, and which also extends away from the top surface 206 in the same direction as the first side surface 208, where the first side surface 208 and the second side surface 210 are at least substantially parallel to each other. As a result, the top surface 206 covers the longitudinal end surface of the storage media device 104, the first side surface 208 covers a portion of a first side surface of the storage media device 104, and the second side surface 210 covers a portion of a second side surface of the storage media device 104, where the second side surface of the storage media device 104 is opposite from the first side surface of the storage media device 104.

The end cap 204, with the top surface 206, first side surface 208 and second side surface 210 provides a thermal containment for the storage media device 104. With a plurality of storage media devices 104 positioned within a chassis 102, as shown in FIG. 1, the end caps 204 for each storage media device 104 facilitate thermal containment without the need for a separate lid on the chassis 102. That is, the wrap-around end caps 204 for each carrier 200 associated with each storage media device 104 facilitates a top-loaded chassis that provides thermal and air flow management without a separate lid.

Referring back to FIG. 2, in at least some embodiments, the first side surface 208 may include an electromagnetic interference (EMI) containment feature 212. In addition, the frame 202 may further include one or more additional EMI containment features 212, such as on the EMI containment feature 212 positioned on a third side surface 214 of the frame 202 in FIG. 2, and/or the EMI containment feature 212 positioned on a fourth side surface 216 of the frame 202 in FIG. 4. In the depicted example, the EMI containment features 212 are configured as EMI fingers that may form gaskets. The EMI fingers may be made from metal, fabric over foam, or any other known and suitable materials for EMI containment.

The EMI containment features 212, in combination with the end cap 204 facilitate EMI containment in a lidless chassis 102. For example, in the embodiment shown in FIGS. 2 through 5, the EMI containment feature 212 on the first side surface 208 of the end cap 204 can interface with the second side surface 210 of an adjacent carrier and storage media device 104 within the chassis 102 to substantially seal off the area below the end cap 204 from electromagnetic interference, and to aid in the thermal containment of the data storage system 100. Similarly, the EMI containment feature 212 on the third side surface 214 of an end cap 204, and/or on the fourth side surface 216 of an end cap 204 can interface with the side surface of an adjacent carrier and storage media device 104 within the chassis 102 to substantially seal off the area below the end cap 204.

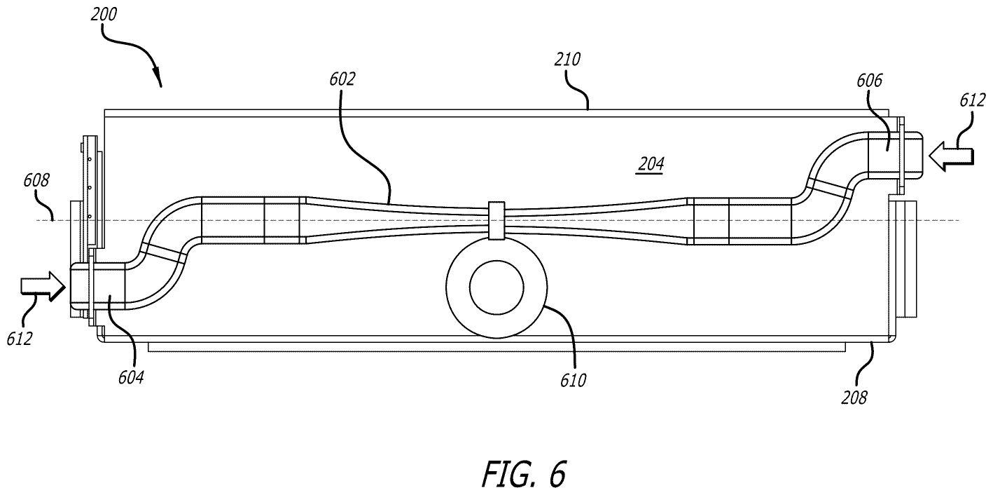

Referring to FIG. 6, in some embodiments of a carrier 200, a latching mechanism 602 may be included. Using the example of the carrier 200 with the end cap 204 described above, the latching mechanism 602 may be positioned over, or on top of, the end cap 204 (as oriented in FIGS. 2 through 5). According to aspects of the present disclosure, the latching mechanism 602 includes a first longitudinal end 604 and an opposing second longitudinal end 606 that extend outward from opposing lateral edges of the end cap 204 in an offset pattern. As used herein, an offset pattern refers to each longitudinal end 604, 606 extending outward from a lateral edge of the end cap 204 at opposing offsets relative to a centerline, central plane, or central axis identified by element number 608 in FIG. 6. For simplicity, it will be referred herein as a centerline 608, which extends through a center of the end cap 204.

As shown, the first longitudinal end 604 of the latching mechanism 602 is positioned to extend outward from a lateral edge of the end cap 204 on a side of the centerline 608 closer to the first side surface 208 of the end cap 204. On the other side, the second longitudinal end 606 is positioned to extend outward from an opposing lateral edge of the end cap 204 on a side of the centerline 608 closer to the second side surface 210.

The latching mechanism 602 may be formed of plastic, metal, rubber, or combinations thereof. Although the depicted example shows a single piece embodiment, it will be apparent that the latching mechanism 602 may be implemented using multiple structures coupled together in other embodiments. Additionally, the latching mechanism 602 may include a latch pull ring 610, or some other element to cause the first longitudinal end 604 and the second longitudinal end 606 to move inward relative to the lateral edge of the end cap 204, as indicated by the arrows 612. In other words, although a latch pull ring 610 is shown, it should be understood that any other actuator mechanism to actuate the first longitudinal end 604 and the second longitudinal end 606 to move inward at the same time.

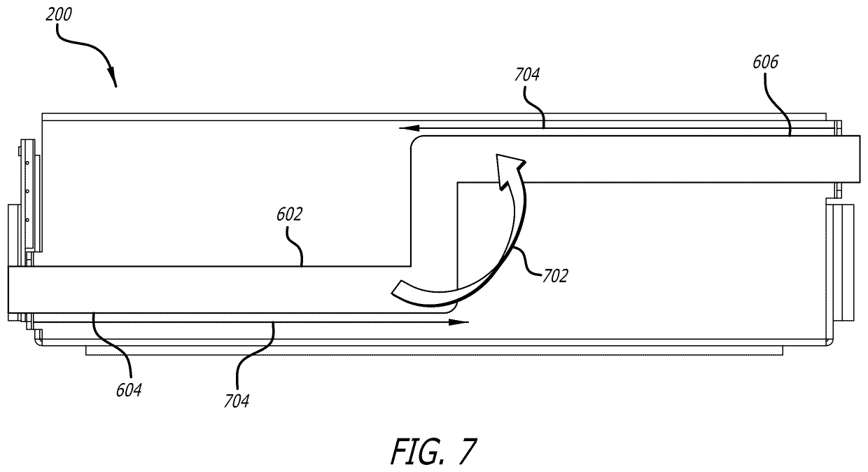

FIG. 7 is a block diagram showing different motions that may be implemented by to actuate the two longitudinal ends 604, 606 to move inward. For example, the mechanism may actuate the two longitudinal ends 604, 606 by twisting a moment arm in the direction shown by arrow 702, causing the two longitudinal ends 604, 606 to move inward in the direction of arrow 704. In another example, the mechanism may operate as a pull ring/tab that pulls the two longitudinal ends 604, 606 inward as the pull ring/tab is pulled by a user.

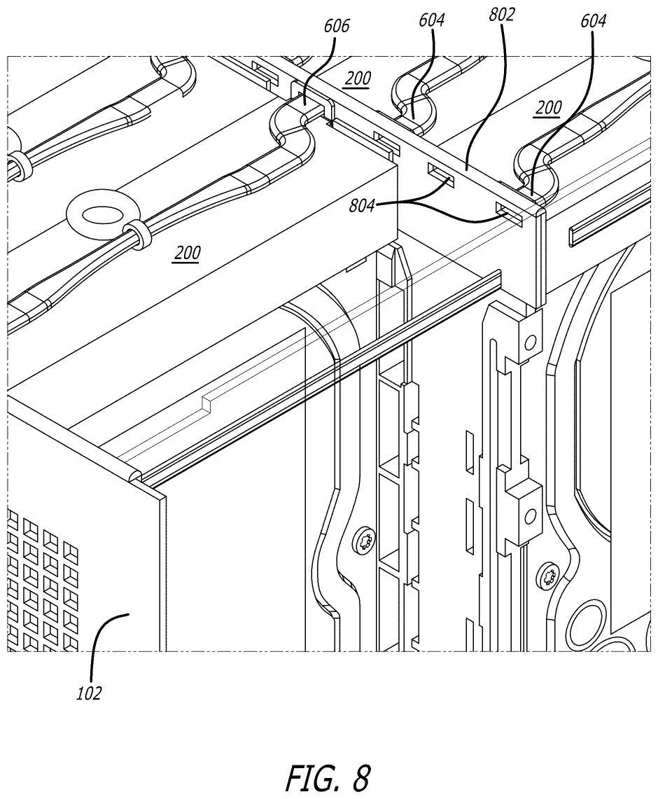

The two longitudinal ends 604, 606 that facilitate latching can improve latching compared to many conventional carriers with just a single latch on one side of the carrier. For example, the latching mechanism 602 of the present disclosure can facilitate latching on both sides of the carrier. As shown in FIG. 8, the two longitudinal ends 604, 606 of adjacent carriers within the chassis 102 do not share the same aperture in the divider walls 802 as a result of the offset pattern described herein. As such, each longitudinal end 604, 606 can penetrate deeper into its respective aperture 804, which can improve the retention of each carrier within the chassis 102. In some embodiments the divider walls 802 within the chassis 102 can be formed of an electrically conductive material to facilitate electrostatic dissipation (ESD) as well as act as a component of the overall EMI containment of a lidless design.

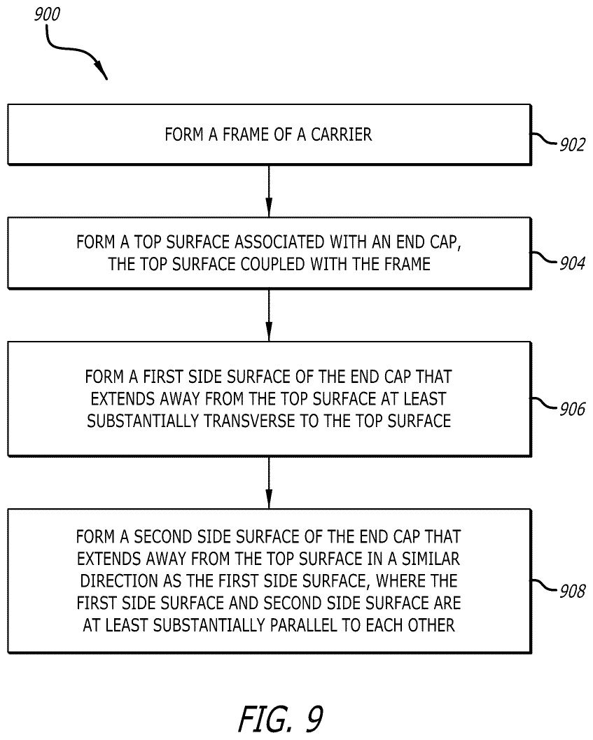

Additional aspects of the present disclosure include methods of making a data storage system including at least one carrier, such as the carrier 200. FIG. 9 is a flow diagram depicting at least one example of a method of making a data storage system. With reference to FIGS. 1-9, an example of at least one implementation of a method may include forming a frame 202 of a carrier 200 at step 902. At step 904, a top surface 206 may be formed, where the top surface 206 is associated with an end cap 204, and where the top surface 206 is coupled with the frame 202.

At 906, a first side surface 208 of the end cap 204 may be formed, where the first side surface 208 extends away from the top surface 206 at least substantially transverse to the top surface 206. In one or more implementations, forming the first side surface 208 of the end cap 204 can include forming an EMI containment feature 212 on the first side surface 208 of the end cap 204.

At 908 a second side surface 210 of the end cap 204 may be formed, where the second side surface 210 extends away from the top surface 206 in a similar direction as the first side surface 208. The first side surface 208 and the second side surface 210 can be at least substantially parallel to each other, according to various implementations.

In some implementations of the method, a storage media device 104 may be coupled to the carrier 200 with the end cap 204 extending over and covering a longitudinal end surface of the storage media device 104. The first side surface 208 of the end cap 204 and the second side surface 210 of the end cap 204 can extend over a portion of respective side surfaces of the storage media device 104. With a storage media device 104 coupled to each carrier 200, each carrier 200 can be disposed in a chassis 102. As described herein above, disposing a plurality of carriers 200, each coupled with a respective storage media device 104 in the chassis 102 can facilitate thermal containment by the end cap 204 of each respective carrier 200 within the chassis 102. Accordingly, the chassis may be lidless. Additionally or alternatively, disposing the plurality of carriers 200, each coupled with a respective storage media device 104 in the chassis 102 can facilitate EMI containment by the end cap 204 of each respective carrier 200 within the chassis 102. Again, such features may facilitate use of a lidless chassis 102.

In some implementations, a latching mechanism 602 may be positioned over the end cap 204. The latching mechanism 602 can include a first longitudinal end 604 and an opposing second longitudinal end 606 that each extend outward from opposing lateral edges of the end cap 204 in an offset pattern, as described herein above. The carrier 200 may then be disposed in the chassis 102 with the first longitudinal end 604 of each latching mechanism 602 extending into a respective aperture 804 in a divider wall 802 of the chassis 102, and with the second longitudinal end 606 of each latching mechanism 602 extending into a respective aperture 804 in the divider wall 802 of the chassis 102.

While the above discussed aspects, arrangements, and embodiments are discussed with specific details and particularity, one or more of the components, steps, features and/or functions illustrated in FIGS. 1, 2, 3, 4, 5, 6, 7, 8, and/or 9 may be rearranged and/or combined into a single component, step, feature or function or embodied in several components, steps, or functions. Additional elements, components, steps, and/or functions may also be added or not utilized without departing from the present disclosure. The apparatus, devices and/or components illustrated in FIGS. 1, 2, 3, 4, 5, 6, 7, and/or 8 may be configured to perform or employ one or more of the methods, features, parameters, and/or steps described in FIG. 9.

While features of the present disclosure may have been discussed relative to certain embodiments and figures, all embodiments of the present disclosure can include one or more of the advantageous features discussed herein. In other words, while one or more embodiments may have been discussed as having certain advantageous features, one or more of such features may also be used in accordance with any of the various embodiments discussed herein. In similar fashion, while exemplary embodiments may have been discussed herein as device, system, or method embodiments, it should be understood that such exemplary embodiments can be implemented in various devices, systems, and methods.

Also, it is noted that at least some implementations have been described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features associated with the examples described herein and shown in the accompanying drawings can be implemented in different examples and implementations without departing from the scope of the present disclosure. Therefore, although certain specific constructions and arrangements have been described and shown in the accompanying drawings, such embodiments are merely illustrative and not restrictive of the scope of the disclosure, since various other additions and modifications to, and deletions from, the described embodiments will be apparent to one of ordinary skill in the art. Thus, the scope of the disclosure is only determined by the literal language, and legal equivalents, of the claims which follow.

What is claimed is:

1. A storage media carrier, comprising:
a frame; and
an end cap coupled with the frame, the end cap including
a top surface,
a first side surface that extends away from the top surface at least substantially transverse to the top surface, and
a second side surface that extends away from the top surface in a similar direction as the first side surface, wherein the first side surface and the second side surface are at least substantially parallel to each other.

2. The storage media carrier of claim 1, further comprising an electromagnetic interference (EMI) containment feature positioned on the first side surface of the end cap.

3. The storage media carrier of claim 2, wherein the EMI containment feature comprises an EMI finger forming a gasket.

4. The storage media carrier of claim 2, wherein the EMI containment feature is formed with at least one of metal or fabric over foam.

5. The storage media carrier of claim 1, further comprising a latching mechanism positioned over the end cap, the latching mechanism including a first longitudinal end and an opposing second longitudinal end that each extend outward from opposing lateral edges of the end cap in an offset pattern.

6. The storage media carrier of claim 5, wherein the latching mechanism includes an actuator mechanism configured to displace the first longitudinal end and the second longitudinal end inward relative to a lateral edge of the end cap.

7. A data storage assembly, comprising:
a plurality of storage media devices, each storage media device including a respective longitudinal end surface; and
a respective carrier comprising a frame coupled to each of the plurality of storage media devices, wherein each frame includes an end cap that extends over and covers the longitudinal end surface of the respective storage media device and wraps around a portion of a side surface of the respective storage media device.

8. The data storage assembly of claim 7, further comprising a chassis in which each of the plurality of storage media devices and each respective carrier are positioned.

9. The data storage assembly of claim 8, wherein each end cap comprises an electromagnetic interference (EMI) containment feature, the EMI containment within the chassis being formed by the end caps of each respective carrier for each of the plurality of storage media devices.

10. The data storage assembly of claim 8, wherein thermal containment within the chassis is formed by the end caps of each respective carrier for each of the plurality of storage media devices.

11. The data storage assembly of claim 7, wherein each end cap comprises:
a top surface that extends over and covers the longitudinal end surface of the respective storage media device;
a first side surface that extends away from the top surface at least substantially transverse to the top surface; and
a second side surface that extends away from the top surface in a similar direction as the first side surface, where the first side surface and the second side surface are at least substantially parallel to each other.

12. The data storage assembly of claim 11, wherein each end cap comprises an electromagnetic interference (EMI) containment feature positioned on the first side surface.

13. The data storage assembly of claim 7, further comprising a latching mechanism positioned over the end cap, the latching mechanism including a first longitudinal end and an opposing second longitudinal end that each extend outward from opposing lateral edges of the end cap in an offset pattern.

14. A method of making a data storage system, the method comprising:
forming a frame of a carrier; and
forming a top surface associated with an end cap, the top surface coupled with the frame;
forming a first side surface of the end cap that extends away from the top surface at least substantially transverse to the top surface; and
forming a second side surface of the end cap that extends away from the top surface in a similar direction as the first side surface, wherein the first side surface and the second side surface are at least substantially parallel to each other.

15. The method of claim 14, further comprising:
coupling a storage media device to the carrier with the end cap extending over and covering a longitudinal end surface of the storage media device, wherein the first side surface of the end cap and the second side surface of the end cap extend over a portion of respective side surfaces of the storage media device; and
disposing the carrier with the coupled storage media device in a chassis.

16. The method of claim 15, wherein disposing the carrier with the coupled storage media device in the chassis comprises:
disposing a plurality of carriers, each coupled with a respective storage media device in the chassis to facilitate thermal containment by the end cap of each respective carrier within the chassis.

17. The method of claim 15, wherein disposing the carrier with the coupled storage media device in the chassis comprises:
disposing a plurality of carriers, each coupled with a respective storage media device in the chassis to facilitate electromagnetic interference (EMI) containment by the end cap of each respective carrier within the chassis.

18. The method of claim 14, wherein forming the first side surface of the end cap comprises:
forming an electromagnetic interference (EMI) containment feature on the first side surface of the end cap.

19. The method of claim 14, further comprising:
positioning a latching mechanism over the end cap, the latching mechanism including a first longitudinal end and an opposing second longitudinal end that each extend outward from opposing lateral edges of the end cap in an offset pattern. 20 The method of claim 19, further comprising:
coupling a storage media device to the carrier with the end cap extending over and covering a longitudinal end surface of the storage media device, wherein the first side surface of the end cap and the second side surface of the end cap extend over a portion of respective side surfaces of the storage media device; and
disposing the carrier with the coupled storage media device in a chassis with the first longitudinal end of each latching mechanism extending into an aperture in a divider wall of the chassis, and with the second longitudinal end of each latching mechanism extending into an aperture in the divider wall of the chassis.
